(19) United States
(12) Patent Application Publication
(10) Pub. No.: US 2005/0264985 A1
(43) Pub. Date: Dec. 1, 2005

(54) Plasma display device

(76) Inventors: Sok-San Kim, Suwon-si (KR); Won-Kyu Bang, Suwon-si (KR)

Correspondence Address: MCGUIREWOODS, LLP, 1750 TYSONS BLVD, SUITE 1800, MCLEAN, VA, 22102, US

(21) Appl. No.: 11/138,439

(22) Filed: May 27, 2005

(30) Foreign Application Priority Data
May 28, 2004 (KR) 10-2004-0038295
Dec. 8, 2004 (KR) 10-2004-0102947

(51) Int. Cl. H01K 1/58; H01J 61/52; H01J 1/02; H01J 7/24; G06F 1/16; H05K 5/00; H05K 7/00

(52) U.S. Cl. 361/681

(57) ABSTRACT

A plasma display device including a plasma display panel for displaying images, a chassis base coupled to the plasma display panel, a reinforcing member coupled to the chassis base, and a supporting member coupled to the reinforcing member.

### CROSS REFERENCE TO RELATED APPLICATION

This application claims priority to and the benefit of Korean Patent Application No. 10-2004-0038295, filed on May 28, 2004, and Korean Patent Application No. 10-2004-0102947, filed on Dec. 8, 2004, which are hereby incorporated by reference for all purposes as if fully set forth herein.

### BACKGROUND OF THE INVENTION

1. Field of the Invention

The present invention relates to a plasma display device, and more particularly, to a plasma display device that disperses a load at support regions and includes a reinforcing structure.

2. Discussion of the Background

A plasma display device displays images through gas discharge. It may have many advantages over other display configurations, including superior display capacity, brightness, contrast, and a wide viewing angle. Furthermore, it may be lightweight, thin, and have a large screen. Consequently, the plasma display device is experiencing increasingly widespread use. Depending upon its mounting structure, the plasma display device may be placed upright on a television stand or other such mounting assembly, or it may be mounted on a wall.

The conventional plasma display device includes a plasma display panel (PDP) for displaying images, a chassis base coupled to the PDP, a plurality of circuit boards coupled to the chassis base on a side opposite the PDP, and a cover (i.e., a front cover and a rear cover) housing the PDP, the chassis base, and the circuit boards.

A wall-mounting holder or a stand holder may be coupled to the rear cover by a bolt or screw inserted in a support boss formed on the chassis base.

The chassis base support boss is typically assembled by press-fitting, welding, spinning, or other such processes. The support boss may be directly coupled to the wall-mounting or stand holder, together with the rear cover, to thereby secure the plasma display device to the holder.

However, this structure concentrates the load of the plasma display device on the support boss. This may loosen the connection between the boss and the chassis base, and it may cause other problems that adversely affect the plasma display device's overall quality.

Further, the plasma display device may have a bracket structure coupled to the chassis base to secure a wall-mounting support. But the bracket structure is generally connected to an external area of the chassis base because of the presence of the circuit boards and other structural elements. This may warp the chassis base's center area and cause other similar deformations.

### SUMMARY OF THE INVENTION

The present invention provides a plasma display device that disperses a load transferred through mounting connections over the chassis base, thereby providing a secure support structure and enhancing overall product quality.

Additional features of the invention will be set forth in the description which follows, and in part will be apparent from the description, or may be learned by practice of the invention.

The present invention discloses a plasma display device including a plasma display panel for displaying images, a chassis base coupled to the plasma display panel, a reinforcing member coupled to the chassis base, and a supporting member coupled to the reinforcing member.

The present invention also discloses a plasma display device including a plasma display panel, a chassis base coupled to the plasma display panel, a reinforcing member coupled to the chassis base, a supporting member coupled to the reinforcing member, a bracket member extending in a direction intersecting the reinforcing member, and coupled to the supporting member, and a fixing member coupled to the bracket member.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

FIG. 1 is an exploded perspective view of a plasma display device according to a first exemplary embodiment of the present invention.

FIG. 2 is a partial perspective view of the plasma display device of FIG. 1.

FIG. 3 is a sectional view taken along line A-A of FIG. 2.

FIG. 4 is a partial sectional view of a plasma display device according to a second exemplary embodiment of the present invention.

FIG. 5 is a partial sectional view of a plasma display device according to the second exemplary embodiment of the present invention.

FIG. 6 is a perspective view of a supporting member of a plasma display device according to a third exemplary embodiment of the present invention.

FIG. 7 is a perspective view of a supporting member of a plasma display device according to a fourth exemplary embodiment of the present invention.

FIG. 8A is a partial sectional view of a plasma display device according to a fifth exemplary embodiment of the present invention, and FIG. 8B is a partial rear view of a reinforcing member and a supporting member of FIG. 8A.

FIG. 9 is a partial sectional view of a plasma display device according to the fifth exemplary embodiment of the present invention.

FIG. 10 is a partial sectional view of a plasma display device according to the fifth exemplary embodiment of the present invention.

FIG. 11 is a partial sectional view of a plasma display device according to the fifth exemplary embodiment of the present invention.

FIG. 12A is a partial sectional view of a plasma display device according to a sixth exemplary embodiment of the present invention, and FIG. 12B is a partial rear view of a reinforcing member and a supporting member of FIG. 12A.

FIG. 13 is a partial sectional view of a plasma display device according to a seventh exemplary embodiment of the present invention.

FIG. 14 is a perspective view of a chassis base of plasma display device according to an eighth exemplary embodiment of the present invention.

FIG. 15 is a partial enlarged perspective view of area B of FIG. 14.

FIG. 16 is a partial sectional view taken along line D-D of FIG. 15.

FIG. 17 is a partial enlarged perspective view of area C of FIG. 14.

### DETAILED DESCRIPTION OF THE ILLUSTRATED EMBODIMENTS

Exemplary embodiments of the present invention will now be described with reference to the drawings.

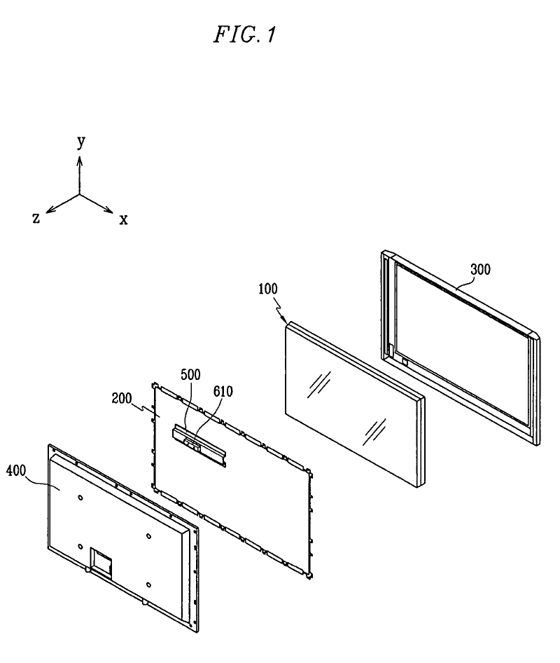

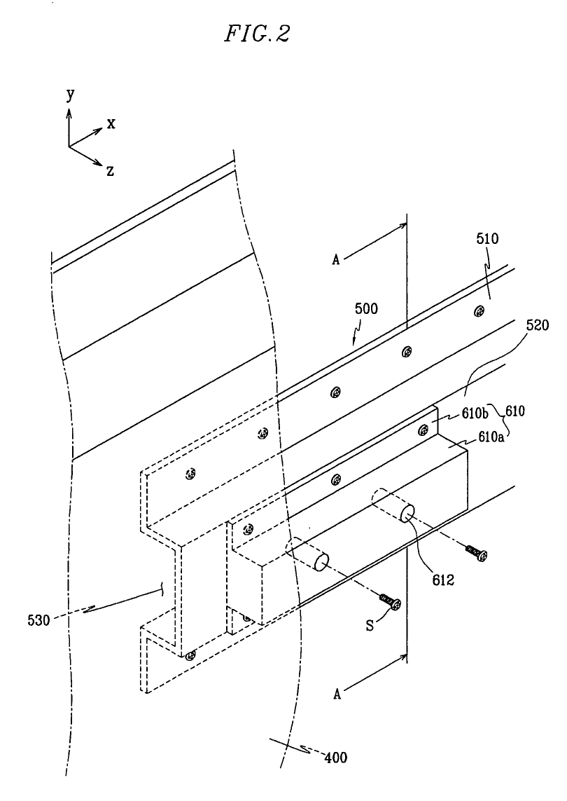

FIG. 1 is an exploded perspective view of a plasma display device according to a first exemplary embodiment of the present invention.

Referring to FIG. 1, the plasma display device may include a PDP 100 for displaying images using a gas discharge process, a chassis base 200 coupled to one side of the PDP 100, a front cover 300 and a rear cover 400. The front and rear covers 300 and 400 may be mounted adjacent to outer surfaces of the PDP 100 and the chassis base 200, respectively, to secure the PDP 100 and the chassis base 200 therebetween. One or more circuit boards (not shown) may be coupled to a side of the chassis base 200 that is opposite to the PDP 100. The circuit board(s) may include drive circuit elements for driving the PDP 100.

A reinforcing member 500 may be coupled to the chassis base 200, and a supporting member 610 may be coupled to the reinforcing member 500. As FIG. 3 shows, a wall-mounting or stand holder H may be coupled to the supporting member 610, thereby mounting the plasma display device on a wall or a stand.

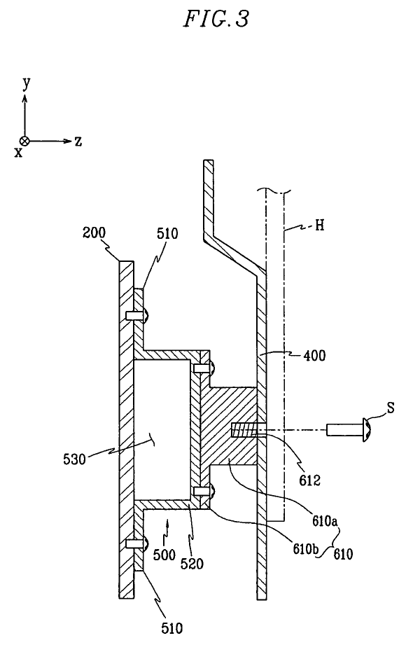

FIG. 2 is a partial perspective view of the plasma display device of FIG. 1, and FIG. 3 is a sectional view taken along line A-A of FIG. 2.

Referring to FIG. 2 and FIG. 3, the reinforcing member 500 may be coupled to the rear surface of the chassis base 200. It may include a pair of substantially parallel first flanges 510 contacting the chassis base 200 and a protruding segment 520 interposed between the first flanges 510. The protruding segment 520 includes a protruding surface apart from, and substantially parallel to, the chassis base's rear surface and a pair of protruding sidewalls interconnecting the protruding surface and the first flanges 510. The protruding segment 520 defines a cavity 530 between its protruding surface and sidewalls and the chassis base's rear surface. This reinforcing member structure provides sufficient strength without adding too much weight.

The first flanges 510 may include a plurality of passage holes so that the reinforcing member 500 may be screwed to the rear surface of the chassis base 200. The reinforcing member 500 may cover a large portion of the chassis base's available space. This permits dispersal of the plasma display device's load over a large area of the chassis base 200 when coupling the device to a holder.

The supporting member 610 may be coupled to an outer surface of the protruding surface of the protruding segment 520 by a connecting means such as screws S. The supporting member 610 may include a body section 610a, which extends from the protruding segment's 520 protruding surface, and a pair of second flanges 610b, which extend from opposite sides of the body section 610a and are coupled to the protruding segment's protruding surface. One or more screw holes 612 may be formed in the supporting member's 610 body section 610a. Bolts or screws may pass through the holder H, and the rear cover 400, and be coupled to the screw holes 612.

The reinforcing member 500 and the supporting member 610 may be made of a conductive material that is capable of blocking electromagnetic interference (EMI). For example, they may be made of a metal or a synthetic resin containing metal powder or metal microfilaments. Further, they may be formed of a synthetic resin material and plated with a conductive metal material or deposited with pigments.

In the plasma display device of the first exemplary embodiment, the reinforcing member's 500 first flanges 510 may be coupled to the chassis base's 200 rear surface using, for example, screws, and the supporting member 610 may be screwed to the protruding segment 520. The supporting member 610 may be coupled to the holder H by, for example, screws or bolts passing through the holder H and the rear cover 400. In this configuration, the plasma display device's load may be transmitted to areas where the supporting member 610 and the holder H are coupled, and the load transmitted to the supporting member 610 may be dispersed over the chassis base 200 through the protruding segment 520 and the first flanges 510. Accordingly, instead of being concentrated on a support boss, the plasma display device's load may be dispersed over a large area, thereby helping ensure product reliability.

Further, since the reinforcing member 500 increases the chassis base's strength, a more sturdy structure may be realized for thinner and larger plasma display devices.

Additionally, the reinforcing member 500 and the supporting member 610 may block EMI generated in the area of the drive circuit elements, which is a very useful advantage in a structure that does not have a separate EMI-blocking means.

The supporting member 610 may be made using an injection, casting, or other like processes.

In the first exemplary embodiment, although the rear cover 400 is coupled to the supporting member 610 using a connecting means such as a screw S, an additional reinforcing member, such as a bracket, may be coupled to the supporting member 610. This is also true for the embodiments described below.

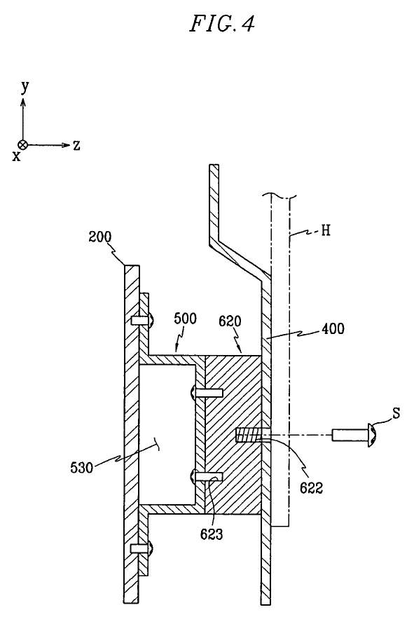

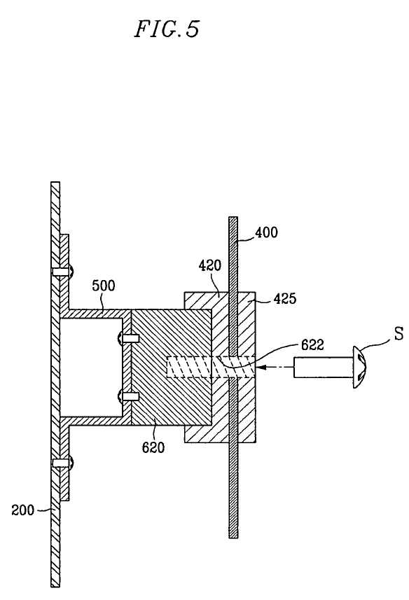

FIG. 4 is a partial sectional view of a plasma display device according to a second exemplary embodiment of the present invention.

Referring to FIG. 4, unlike the first exemplary embodiment, a supporting member 620 does not include the second flanges 610b, and it is formed having substantially a hexahedral shape. Further, one or more screw holes 622 may be formed in the supporting member 620 to allow coupling with the holder H. Also, unlike in the first exemplary embodiment, the supporting member 620 may be screwed to the reinforcing member 500 from a side of the cavity 530. That is, the supporting member 620 may include screw holes 623 formed in its surface opposing the reinforcing member 500. This configuration forms a larger contact area between the reinforcing member 500 and the supporting member 620, thereby providing for a more stable connection with the holder H. Further, the supporting member's 620 relatively simple hexahedral shape may permit lower manufacturing costs. Another advantage of this structure is that coupling the reinforcing member 500 and the supporting member 620 through the side of the cavity 530 permits a thinner supporting member 620. Other aspects of the structure and application of the plasma display device of this embodiment are similar to those of the first exemplary embodiment.

FIG. 5 is a partial sectional view of a plasma display device according to a modified example of the second exemplary embodiment of the present invention.

Referring to FIG. 5, auxiliary elements 420, 425 may be interposed between the supporting member 620 and the rear cover 400, and between the rear cover 400 and the screw S, respectively. The auxiliary elements 420, 425 may improve the reliability of the connection between these elements. The auxiliary elements 420, 425 may be made of a conductive or non-conductive material.

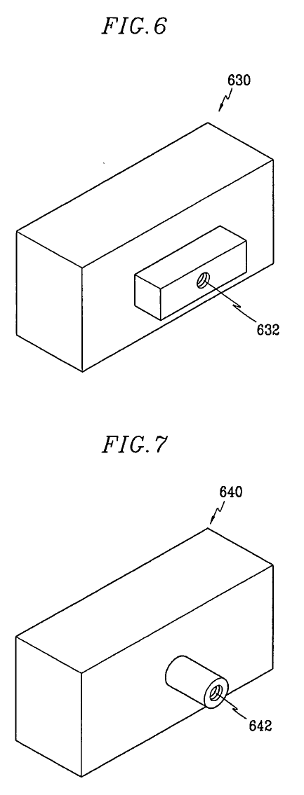

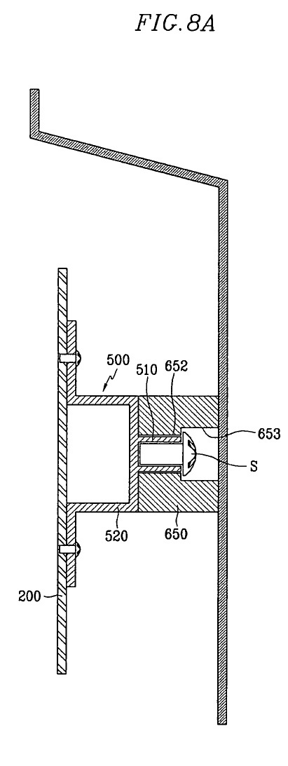

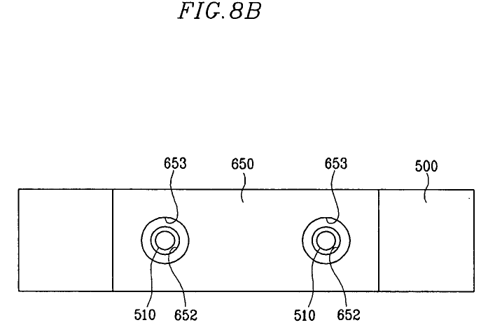

FIG. 6 and FIG. 7 are perspective views of supporting members 630, 640 according to third and fourth exemplary embodiments of the present invention, respectively.

As FIG. 6 shows, the supporting member 630 of the third exemplary embodiment of the present invention includes a hexahedral shaped protrusion having a screw hole 632. As FIG. 7 shows, the supporting member 640 of the fourth exemplary embodiment includes a cylindrical shaped protrusion having a screw hole 642. The shape of the protrusions and the screw holes may vary as desired. Further, the supporting members 630, 640 may be coupled to the reinforcing member 500 using screws S as described with reference to the first and second exemplary embodiments.

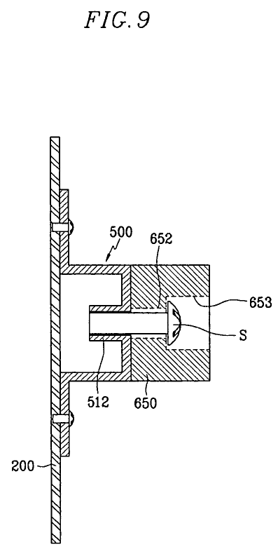

FIG. 8A is a partial sectional view of a plasma display device according to a fifth exemplary embodiment of the present invention, and FIG. 8B is a partial rear view of a reinforcing member 500 and a supporting member 650 of FIG. 8A.

Referring to FIG. 8A and FIG. 8B, the reinforcing member 500 may include a boss 510 formed extending from a protruding surface of a protruding segment 520. The supporting member 650 may include a first passage hole 652, into which the boss 510 is inserted, and a second passage hole 653, which has a greater diameter than the first passage hole 652. A head of a screw S coupled to the boss 510 may be positioned in the second passage hole 653. The screw S coupling the reinforcing member 500 and the supporting member 650 is not exposed in this configuration.

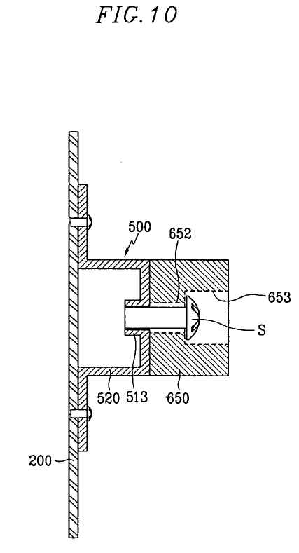

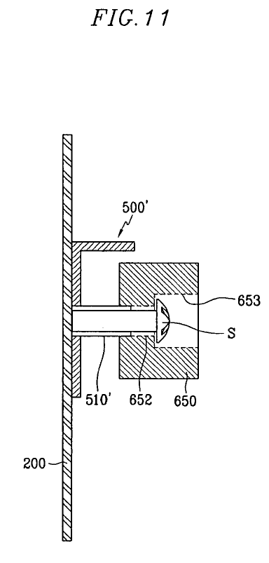

FIG. 9, FIG. 10 and FIG. 11 show partial sectional views of a plasma display device according to modified examples of the fifth exemplary embodiment of the present invention.

Referring to FIG. 9, a boss 512 may be formed in the reinforcing member 500, and it may protrude towards the chassis base 200. Referring to FIG. 10, a burr 513 may be formed on the reinforcing member's protruding segment 520 to allow coupling using a screw S.

Referring to FIG. 11, a reinforcing member 500′ may be formed having an angled element. A boss 510′ may protrude from the chassis base 200, and it is inserted in the first passage hole 652 of the supporting member 650. A screw S may be inserted into the boss 510′, thereby coupling the supporting member 650 to the reinforcing member 500′.

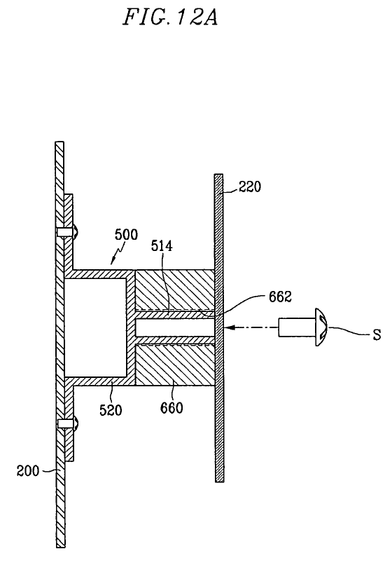

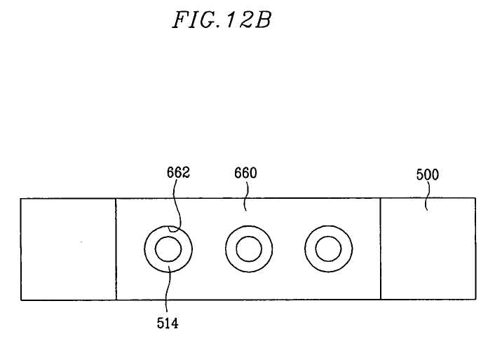

FIG. 12A is a partial sectional view of a plasma display device according to a sixth exemplary embodiment of the present invention, and FIG. 12B is a partial rear view of a reinforcing member and a supporting member of FIG. 12A.

Referring to FIG. 12A, a reinforcing member 500 may include a boss 514 that protrudes from its protruding segment 520. A passage hole 662 may be formed in a supporting member 660, and the boss 514 may be inserted in the passage hole 662. A bracket member 220 may be mounted adjacent to the supporting member 660, and a screw S may couple the bracket member 220 to the supporting member 660.

As shown in FIG. 12B, three passage holes 662 may be formed in the supporting member 660. A center passage hole 662 may be used for coupling the bracket member 220 to the supporting member 660, and the passage holes 662 on each side of the center passage hole 662 may be used to couple the supporting member 660 to the reinforcing member 500.

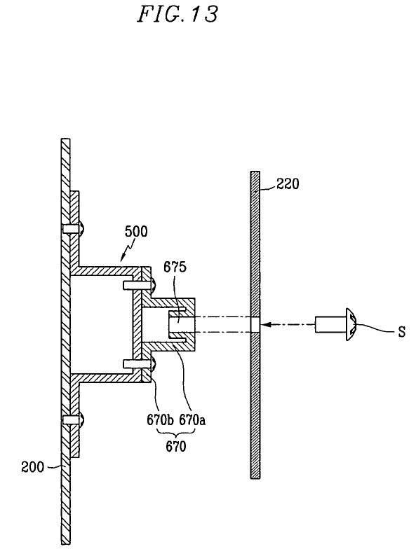

FIG. 13 is a partial sectional view of a plasma display device according to a seventh exemplary embodiment of the present invention.

Referring to FIG. 13, a supporting member 670 may be formed by a press process. The supporting member 670 may include flanges 670b screwed to a reinforcing member 500, and a body section 670a protruding between the flanges 670b and in a direction away from an adjacent surface of the reinforcing member 500. A boss 675 may protrude toward the reinforcing member 500 from a distal end of the body section 670a. A screw S may be inserted into the boss 675 to couple the supporting member 670 and a bracket member 220.

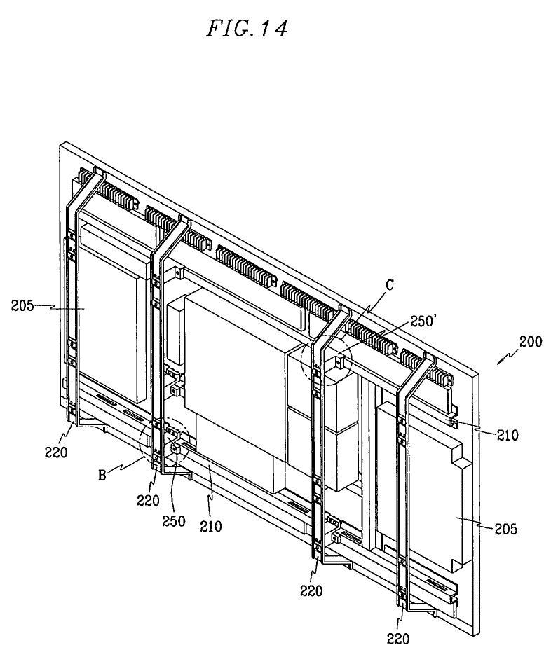

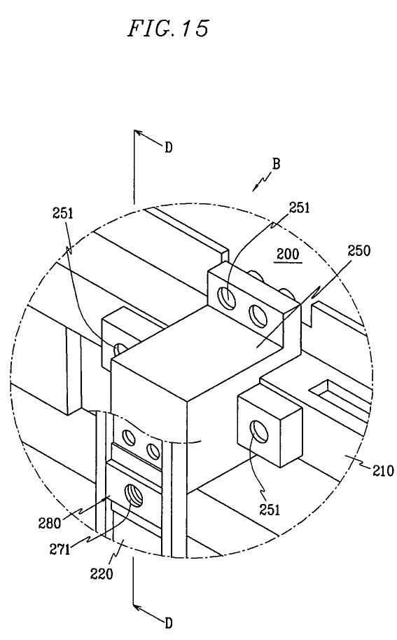

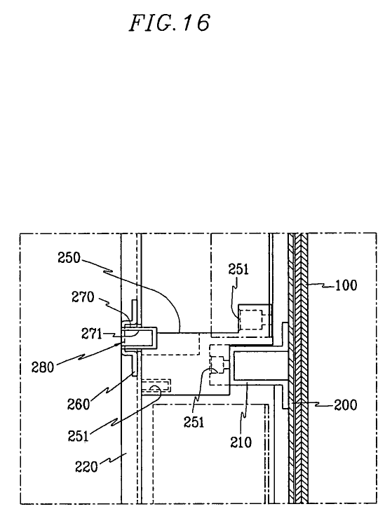

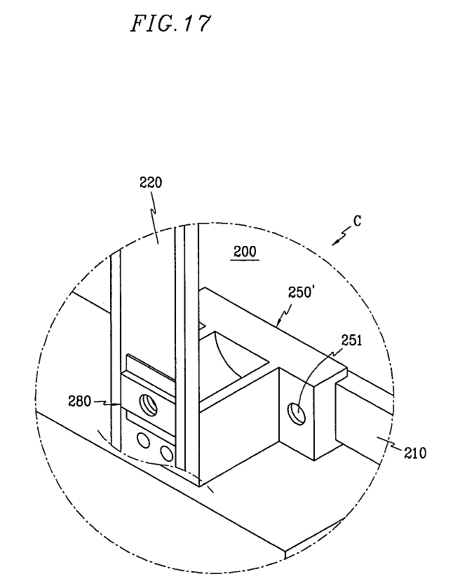

FIG. 14 is a perspective view of a chassis base of the plasma display device according to an eighth exemplary embodiment of the present invention, FIG. 15 is a partial enlarged perspective view of area B of FIG. 14, FIG. 16 is a partial sectional view taken along line D-D of FIG. 15, and FIG. 17 is a partial enlarged perspective view of area C of FIG. 14.

Referring to FIG. 14 and FIG. 15, a chassis base 200 according to the eighth exemplary embodiment may include reinforcing members 210 coupled to one side thereof and extending horizontally. A plurality of reinforcing members 210 may be mounted adjacent to one another along one or more horizontal lines. The reinforcing members 210 may be coupled to the chassis base 200 by welding, using screws, by TOX joining, or other like methods. The reinforcing members 210 are preferably positioned on the chassis base 200 where circuit boards and other structural elements mounted to the chassis base are not.

Screw holes 251 may be formed in block-shaped supporting members 250, and the supporting members 250 may be coupled to the reinforcing members 210 using screws inserted through the screw holes 251. The supporting members 250 may have different shapes depending on their position. The supporting members 250 may be coupled to the reinforcing members 210 using a variety of means, including using screws.

Bracket members 220 may be coupled to the supporting members 250 using screws or other fastening elements. Preferably, the supporting members 250 are high enough so that the bracket members 220 do not contact the circuit boards 205. The bracket members 220 may be mounted orthogonally to the reinforcing members 210. Further, each end of the bracket members 220 may be coupled to the chassis base 200.

Fixing members 280, used for coupling with wall-mounting structural elements (not shown), may be coupled to the bracket members 220 using screws or by welding. As FIG. 16 shows, the fixing members 280 may include flanges 260 and a screw-coupling segment 270. The flanges 260 may be coupled to the bracket members 220, and the screw-coupling segment 270, which may be located near the center of the fixing member, may include a screw hole 271 to which a screw or bolt may be coupled.

The fixing members 280 preferably have substantially the same shape to enable coupling to the bracket members 220 at corresponding locations using corresponding connection methods. This uniformity may reduce manufacturing costs and increase productivity.

In the plasma display device of this exemplary embodiment, the fixing members 280 may be coupled to the bracket members 220 at locations where wall-mounting structural elements are coupled to the brackets. Further, the wall-mounting structural elements may be coupled, using screws or bolts, to the screw holes 271 of the screw-coupling segments 270 provided on the fixing members 280. By coupling the wall-mounting structural elements to the chassis base 200 in this manner, the supporting members 250 may disperse a load applied to the reinforcing members 210 and the bracket members 220. The load may disperse over the entire region of the chassis base 200, thereby preventing deformation, such as warping, in areas of the chassis base 200 (i.e., its center region).

FIG. 17 shows another possible shape of a supporting member 250′. The supporting member 250′ may be designed having various shapes according to the shape of the reinforcing members 210, the positioning of the circuit boards 205, and the formation of structural elements connected to the chassis base 200. Other aspects, effects, etc. of this embodiment are similar to those of the embodiments described above, and so a description thereof will be omitted.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

1. A plasma display device, comprising:
a plasma display panel for displaying images;
a chassis base coupled to the plasma display panel;
a reinforcing member coupled to the chassis base; and
a supporting member coupled to the reinforcing member.

2. The plasma display device of claim 1, wherein the supporting member is made of a conductive material.

3. The plasma display device of claim 2, wherein the conductive material comprises a metal.

4. The plasma display device of claim 1, wherein the supporting member is formed of a synthetic resin material containing one of a conductive metal powder and metal microfilaments.

5. The plasma display device of claim 1, wherein the supporting member is formed of a synthetic resin material that is plated with a conductive material.

6. The plasma display device of claim 1, wherein the supporting member is coupled to the reinforcing member at two or more points.

7. The plasma display device of claim 1,
wherein the reinforcing member comprises a flange positioned adjacent to the chassis base; and
wherein the flange is coupled to the chassis base.

8. The plasma display device of claim 1, wherein the supporting member includes a hole used for coupling.

9. The plasma display device of claim 8, further comprising:
a rear cover,
wherein the rear cover is fastened to the supporting member with a fastener through the hole.

10. The plasma display device of claim 9, wherein the fastener is one of a screw or a bolt.

11. The plasma display device of claim 8, wherein the supporting member is fastened to a wall-mounting holder with a fastener through the hole.

12. The plasma display device of claim 11, wherein the fastener is one of a screw or a bolt.

13. The plasma display device of claim 8, further comprising:
a bracket member adjacent to the supporting member,
wherein the bracket member is coupled to the chassis base and extends along a direction intersecting the reinforcing member.

14. The plasma display device of claim 8, wherein the hole is formed in a hexahedral-shaped protrusion of the supporting member.

15. The plasma display device of claim 8, wherein the hole is formed in a cylindrical-shaped protrusion of the supporting member.

16. The plasma display device of claim 1, wherein the supporting member comprises:
a body section extending from the reinforcing member; and
a flange extending from the body section and coupled to the reinforcing member.

17. The plasma display device of claim 1,
wherein the supporting member includes a hole in a surface opposing the reinforcing member, and
wherein the supporting member is fastened with a fastener to the reinforcing member through the hole.

18. The plasma display device of claim 17, wherein the fastener is one of a screw or a bolt.

19. The plasma display device of claim 1,
wherein a boss extends from the reinforcing member, and
wherein the supporting member includes a first passage hole into which the boss is inserted.

20. The plasma display device of claim 19,
wherein the supporting member further includes a second passage hole having a diameter that is greater than a diameter of the first passage hole, and
wherein a head of a screw coupled to the boss is positioned in the second passage hole.

21. The plasma display device of claim 1, wherein the supporting member is block-shaped.

22. A plasma display device, comprising:
a plasma display panel;
a chassis base coupled to the plasma display panel;
a reinforcing member coupled to the chassis base;
a supporting member coupled to the reinforcing member;
a bracket member extending in a direction intersecting the reinforcing member, and coupled to the supporting member; and
a fixing member coupled to the bracket member.

23. The plasma display device of claim 22, wherein the supporting member is fastened to the reinforcing member and the bracket member with a fastener.

24. The plasma display device of claim 23, wherein fastener is one of a screw or a bolt.

25. The plasma display device of claim 22,
wherein a screw hole is provided in the fixing member, and
wherein the fixing member overlaps the supporting member.

26. The plasma display device of claim 22, wherein the fixing member includes a flange coupled to the bracket member.
